(19) United States
(12) Patent Application Publication
(10) Pub. No.: US 2010/0096000 A1
(43) Pub. Date: Apr. 22, 2010

(54) Artificial light power generation system

(76) Inventor: David R. Andrade, Sanbornton, NH (US)

Correspondence Address: Lawson & Persson, P.C., P.O. Box 712, Laconia, NH, 03247-0712, US

(21) Appl. No.: 12/288,066

(22) Filed: Oct. 16, 2008

(51) Int. Cl. H01L 31/042

(52) U.S. Cl. 136/246; 136/251

(57) ABSTRACT

An artificial light power generation system that includes a housing, at least one artificial light source disposed within the housing, and at least one photovoltaic panel disposed within the housing in light receiving relation to the artificial light source. The photovoltaic panel includes a direct current electrical output to an inverter, which converts the direct current into alternating current and outputs this alternating current through an alternating current electrical output.

### FIELD OF THE INVENTION

The present invention relates to systems for generating electrical power and, in particular to systems for generating electrical power from light energy.

### BACKGROUND OF THE INVENTION

Rising oil prices and increased concern for the protection of the environment has led to renewed interest in energy conservation and in the development of systems to tap sources of clean renewable energy. One of the most popular sources of clean renewable energy is solar energy.

Solar energy is typically utilized in two ways. The first way that solar energy is used is as a heat source, in which a heat transfer fluid, such as water or glycol, is pumped through a solar collection panel where it is heated. The heat from this fluid is then used to provide heat to dwellings, to water within a hot water heater, of for other uses. The second way that solar energy is used is as a means of supplying electrical power. In these applications, photovoltaic cells absorb solar energy and convert this energy into electrical energy, which may then be used to augment or replace electrical energy supplied by electrical power grids.

Photovoltaic cells were first developed in the 1940's and their method of operation is well known in the art. Current photovoltaic cells take a number of different forms, with the specific materials and orientation of the cells being dependent upon the particular applications in which they are used and the cost constraints surrounding these issues. Since they were first developed, the materials used in the manufacture of photovoltaic cells has varied significantly, and the efficiency of photovoltaic cells has increased dramatically from a mere 1% efficiency in the original cells to over 40% efficiency in some currently available cells. It is anticipated that photovoltaic cell technology will continue to advance such that the cost of such cells will decrease while efficiencies will continue to increase.

When used in connection with residential applications, photovoltaic cells have traditionally been arranged in the form of large panels that are mounted to rooftops or arranged in open outdoor areas where they are able to absorb the maximum amount of sunlight. These cells are successful at generating a significant amount of electrical power. However, they detract significantly from the aesthetics of the residence or yard and, accordingly, many people have been unwilling to use them.

Although photovoltaic cells have traditionally converted light from the sun, these cells work equally well at converting artificial light into electrical power. Further, although artificial lights are energized for large portions of each day in residences, schools, office buildings and the like, for purposes of providing light to its occupants, there has not heretofore been any system for capturing this artificial light and converting it back into useful electrical power.

As explained below, a number of issued patents have recognized the fact that artificial light may be used to produce electrical power and have utilized artificial light sources and photovoltaic cells in various applications. However, none are adapted to convert artificial light into alternating current power that may be used for in residences and office buildings.

U.S. Pat. No. 4,354,115, titled “Photocoupling device”, discloses a device that uses artificial light generated by light emitting diodes as a means for transmitting power from one place to another. Similarly, U.S. Pat. No. 4,730,115, titled “Transformer system and direct current power supply” discloses the use of light to convert AC power into DC power through the use of ah artificial light and a photovoltaic cell. Each of these systems is directed solely to the transmission of power using photovoltaic cells and not to the capture and use of artificial light for residential power. Accordingly, neither includes light sources or photovoltaic cells that are capable of producing amounts of power that are sufficient for this purpose.

U.S. Pat. No. 5,248,931, titled “Laser energized high voltage direct current power supply”, and U.S. Pat. No. 6,265,653, titled “High voltage photovoltaic power converter”, each disclose systems that allow low voltage DC power to be converted into high voltage DC power without the use of an inverter. These systems includes a plurality of laser diodes that are energized using low voltage DC power and generate light that it accepted, by photocells, which convert the light energy into DC power. By connecting a large number of photocells together in series, the low voltage DC power used by the laser lights is converted into high voltage DC power leaving the photocells. The devices disclosed in these patents are effective at converting low voltage DC power to high voltage DC power. However, each requires extremely costly components and is not readily adaptable for use in applications where artificial light is used for supplying ambient light to a room and to generating electrical power. Further, as each seeks to avoid the use of an inverter, neither is readily adapted to convert the high voltage DC power into AC power that may be used in residential applications or stepped up through a DC to DC converter of power controller to supply DC power to a motor for vehicle operation.

Therefore, there is a need for a system for generating electrical power from light energy that does not detract significantly from the aesthetics of the residence or yard, that does not place undue stress on structures and works even in areas having limited sunlight, that may be used to recycle energy from light fixtures, that captures artificial light and converts it into alternating current electrical power, and that does not require the use of expensive or dangerous lights.

### SUMMARY OF THE INVENTION

The present invention is an artificial light power generation system that overcomes the disadvantages inherent in prior art systems. In its most basic form, the system of the present invention includes a housing, at least one artificial light source disposed within the housing, and at least one photovoltaic panel disposed within the housing in light receiving relation to the artificial light source. The photovoltaic panel includes a direct current electrical output to an inverter, which converts the direct current into alternating current, preferably at 240 volts, and outputs this alternating current through an alternating current electrical output.

In a preferred embodiment of the system, the artificial light source is a fluorescent light fixture and the housing is dimensioned for mounting to a ceiling. In these embodiments, the housing includes a closed bottom and an open top and the photovoltaic panel is mounted proximate to the closed bottom of the housing. The fluorescent light fixture is mounted between the photovoltaic panel and the open top of the housing such that light from the at least one fluorescent light fixture irradiates both the photovoltaic panel and an area below the housing. In these embodiments, it is preferred that the fluorescent light fixture be an ultraviolet fluorescent light fixture and that the system also includes a light transmitting cover having an ultraviolet filter for filtering a substantial portion of ultraviolet rays passing therethrough.

In some embodiments of the invention, the system is a closed system that uses light solely for power generation. In some such embodiments, the housing includes base portion shaped as a hollow rectangular prism having an open top and a front panel dimensioned to cover the open top of and prevent a substantially amount of light from escaping from the housing. In such embodiments, it is preferred that the front panel of the housing be rotatably attached to the body of the housing and that the artificial light source be attached to the front panel of the housing.

In other embodiments of the invention, the light source includes at least one fiber optic light source, the photovoltaic panel is a plurality of photovoltaic panels, and each of the plurality of photovoltaic panels is in light receiving communication with at least one of the at least one fiber optic light source. In such systems, it is preferred that the housing be a hollow cylindrical prism having an interior surface of substantially circular cross section, each of the plurality of photovoltaic panels is substantially circular, that a dome shaped reflective cover be mounted to each photovoltaic cell, and that the cells and covers are sandwiched together within the interior surface of the housing.

In some embodiments of the invention, the inverter is omitted and the fiber optic fed photovoltaic panel feeds a high voltage DC to DC converter or power controller to provide continuous power to a DC motor, which would propel a vehicle. The fiber optic light source would be fed from a battery charged by the vehicle electrical system.

Some embodiments of the system also include a power controller in electrical communication with the inverter, an electrical supply panel, and a power grid. In such embodiments, the power controller controls a flow of power to the electrical supply panel from the inverter and the power grid. In some such embodiments, the inverter is a grid-tie inverter and the power controller controls a flow of power to the electrical supply panel from the inverter and the power grid and a flow of power to the power grid from the inverter. In some embodiments, at least one battery is also included. In these embodiments, the power controller controls a flow of power to the electrical supply panel from the inverter and the power grid and to the battery from the inverter.

Due to electrical current limitations created from the photovoltaic panel when utilizing artificial light, some embodiments of the invention also include an interface module capable of stepping up the current to a sufficient level to power the inverter. In some such embodiments, the interface module is preferably a rheostat or current transformer, although other types of interface modules may be used. Similarly, the power from the photovoltaic cell may pass into a battery, which in turn outputs electrical power having the proper amount of current to the inverter.

Therefore, it is an aspect of the invention to provide a system for generating electrical power from light energy that does not detract significantly from the aesthetics of the residence or yard, or create a load hazard for the structure it serves.

It is a further aspect of the invention to provide a system for generating electrical power from light energy that may be used to recycle energy from light fixtures where the photovoltaic cells are mounted directly inside a fixture oriented directly toward the light.

It is a further aspect of the invention to provide a system for generating electrical power from light energy that captures artificial light and converts it into alternating current electrical power.

It is a further aspect of the invention to provide a system for generating electrical power from light energy that does hot require the use of expensive or dangerous lights.

These aspects of the invention are not meant to be exclusive and other features, aspects, and advantages of the present invention will be readily apparent to those of ordinary skill in the art when read in conjunction with the following description, appended claims and accompanying drawings.

### BRIEF DESCRIPTION OF THE DRAWINGS

FIG. 1 is a block diagram showing the operation of a basic embodiment of the power generation system of the present invention.

FIG. 2 is a block diagram showing the operation of one embodiment of the power generation system of the present invention that includes a power controller.

FIG. 3 is a block diagram showing the operation of one embodiment of the power generation system of the present invention that includes a power controller and in which a battery serves both as the interface module and as a power storage unit.

FIG. 4 is a cut away side view of a preferred embodiment of the power generation system of the present invention that takes the form of a ceiling mounted light fixture.

FIG. 5A is a cut away side view of an alternative embodiment of the power generation system of the present invention that is a closed system.

FIG. 5B is a cut away top view of the embodiment of FIG. 5A.

FIG. 6 is a cut away side view of another alternative embodiment of the present invention for use in applications requiring mounting in small spaces.

### DETAILED DESCRIPTION OF THE INVENTION

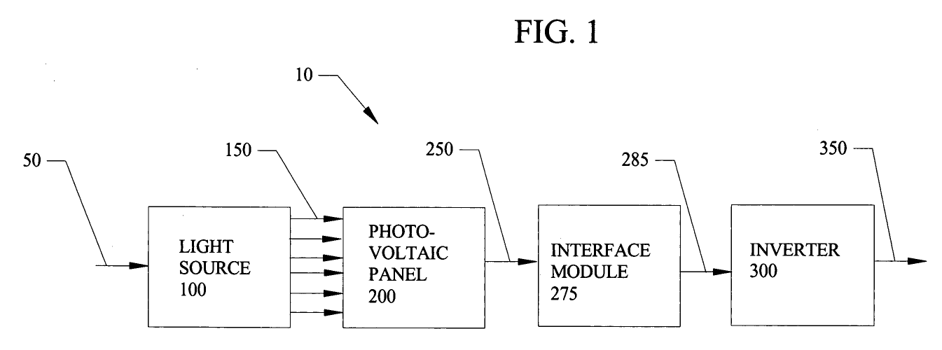

Referring first to FIG. 1, a block diagram showing the operation of the basic embodiment of the artificial light power generation system 10 is shown. An artificial light source 100 in electrical communication with a power input 50 from a source of power (not shown) and converts this power into light 150. The light 150 is absolved by the photovoltaic panel 200, which converts this light energy into direct current electrical energy that is outputted through the direct current electrical output 250. As shown in FIG. 1, the direct current electrical energy flows from the direct current electrical output 250 into an interface module 275, which steps up the current of the electrical energy to a level that may be accepted by the inverter 300. The interface module 275 outputs the electrical power at higher current than received through the direct current electrical output 250 through an interface module output 285 to the inverter 300. The inverter 300 converts the direct current into alternating current electrical energy that is outputted through the alternating current electrical output 350 to an external load (not shown).

The artificial light source 100 may be any artificial source that produces light having wavelengths that may be converted into electrical power by the particular photovoltaic cells that make up the photovoltaic panel 200. Testing has shown that fluorescent, ultraviolet fluorescent, fiber optic, xenon, halogen, mercury vapor, monofilament or LED light sources may be utilized. Ultraviolet sources have been found to produce the highest energy output per power input when used with photovoltaic panels designed for use in direct sunlight. However, it is anticipated that this is a function of the design parameters of the particular photovoltaic panel 200 used during testing and that other artificial light sources 100 may be preferred when used in connection with photovoltaic panels 200 that are designed specifically for that given light source 100.

The photovoltaic panel 200 may also take many forms, provided it is able to accept light energy from the light source and convert this light energy into direct current electrical energy. The preferred photovoltaic panels 200 are 60 Watt, 12 Volt panels, such as those sold by Sunforce Products of Saint-Laurent, Quebec, Canada as part of their 60 Watt Solar Charging Kit. These panels 200 are preferred due to their low cost and sufficient power output. However, it is recognized that other photovoltaic panels 200 may be used to achieve similar results and the slightly more expensive panels may produce superior technical results, albeit at higher cost. Although FIG. 1 shows a single photovoltaic panel and a single light source 100, it is preferred that multiple light sources 100 be directed at multiple photovoltaic panels 200 that are connected together in series prior to the inverter 300. This arrangement produces direct current of higher voltage for provision to the inverter 300 than may be provided by a single panel 200 and this higher voltage is necessary when using the preferred inverter 300.

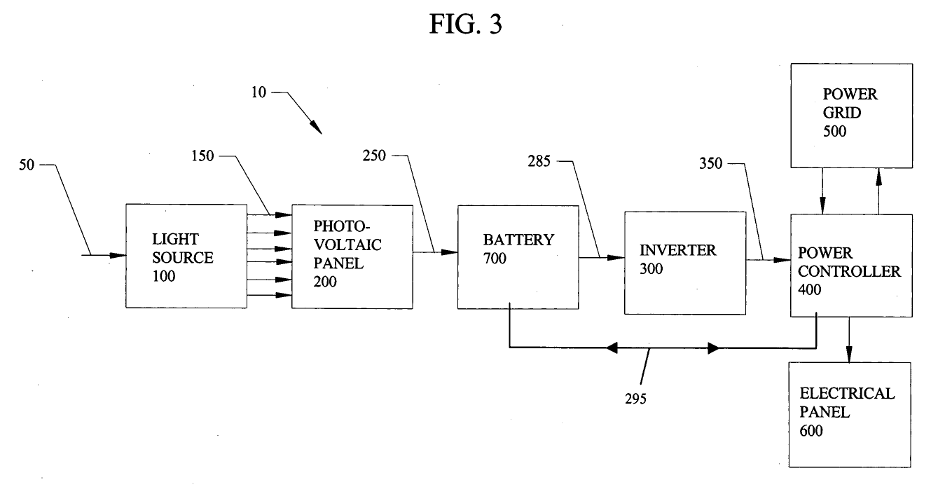

The interface module 275 is required in applications in which the direct current power outputted from the photovoltaic panel 200 is below a threshold current required for operation of the inverter 300. The interface module 250 may be any art recognized device that is capable of stepping up current. In some embodiments, the interface module 275 is a rheostat or current transformer. In others, such as the embodiment described with reference to FIG. 3, it is a battery 700, which accepts the lower current “trickle charge” from the photovoltaic panel 200 and outputs higher current power to the inverter 300. Although the interface module 275 is preferred, it is recognized that it may be omitted in applications in which multiple photovoltaic panels 200 connected in a mariner that outputs power at a current above a threshold current required for operation of the inverter 300, or in applications in which the inverter 300 is capable of accepting power at lower current levels.

The inverter 300 converts the direct current electrical power generated by the photovoltaic panel 200 and converts this direct current into alternating current power that having a voltage that is usable by a residence, commercial building, or for sale back to the power grid. The preferred inverter is a sine wave inverter, such as those sold by Unipower Telecom of Coral Springs, Fla., under the trademark “Gravitas IX12.5 Series”. The Gravitas IX12.5 Series inverters are preferred as they accept a nominal input of between 42 and 56 VDC to output power in the 115V AC at 22 A or 230V AC at 11 A full load range, per module and because up to five separate modules may be stacked into a single unit to produce a maximum output of 12.5 kV A at 115 or 230V AC, 50 or 60 Hz. Further, they may be purchased at a relatively low cost. However, it is recognized that other inverters may be utilized to achieve similar results and that more expensive inverters may produce superior results at lower input voltages.

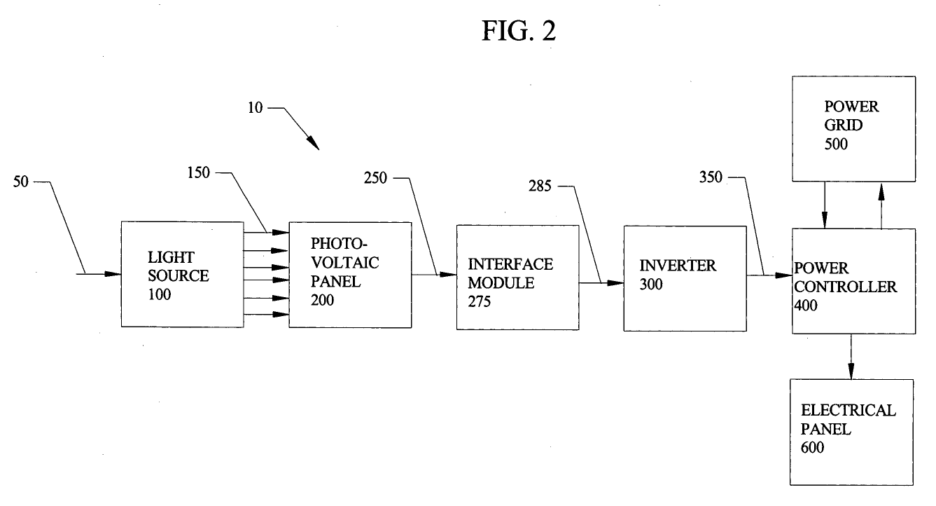

The inverter 300 includes an alternating current output 350 that is connected to an external load (not shown). In some embodiments, this load may be a direct load, such as a hot water heater having an element that is energized in varying degrees based upon the amount of power outputted by the inverter. In such embodiments, there is no need for an additional power controller, as the heater will use whatever power is provided. In other embodiments, such as the embodiments of FIGS. 2 and 3, the output 350 is fed to a power controller 400, which determines whether the power output from the inverter 300 is meets or exceeds the load drawn by the electrical panel 600.

In the embodiment of FIG. 2, the power controller 400 augments power from the inverter 300 with power from the power grid 500 when the power generated by the inverter 300 is insufficient to meet demand, and sends power back to the power grid 500 when power generated by the inverter 300 exceeds demand. In such embodiments, it is preferred that the inverter be a grid-tie inverter that meets the requirements of the power grid 500 and that the power controller 400 include an automatic shut off that senses a cessation in the flow of power from the power grid 500 and prevents power from flowing back into the power grid 500 when such a condition is sensed.

In the embodiment of FIG. 3, a battery 700 serves both as the interface module, stepping up the current, and as a power storage device to store unneeded power during certain circumstances. In such embodiments, direct current power from photovoltaic panel 200 is outputted to the battery 700, which then provides higher current electrical power through its output 285 to the inverter in the same manner as the other types of interface modules 275. It is noted that systems 10 that include a battery 700 are not preferred due to the cost and hazards created by the use of a battery 700. However, as explained below, the use of a battery 700 does provide certain advantages.

In addition to replacing the interface module 275, embodiments utilizing a battery 700 have additional capabilities. Therefore, it is preferred that, in systems utilizing a battery 700, a communication link 295 be established between the battery and the power controller 400 in order to communicate certain information back and forth between the battery 700 and power controller 400. For example, when the battery 700 is discharged to a level where it cannot provide sufficient current to the inverter, the battery 700 would send a signal to the power controller 400 instructing it to use power solely from the power grid 500. In cases where demand is low, the battery 700 is hot fully charged, and the amount of power sold back to the power grid 500 exceeds the power used by the household such that additional power sold to the power grid 500 is sold at a wholesale rather than retail rate, the power controller 400 may send a signal to the battery 700 instructing it to cease the flow of power to the inverter 300 in order to charge it when power generated by the inverter 300 exceeds demand. Finally, in cases where the battery 700 is fully charged, the power controller 400 sends power back to the power grid 500 when power generated by the inverter 300 exceeds demand.

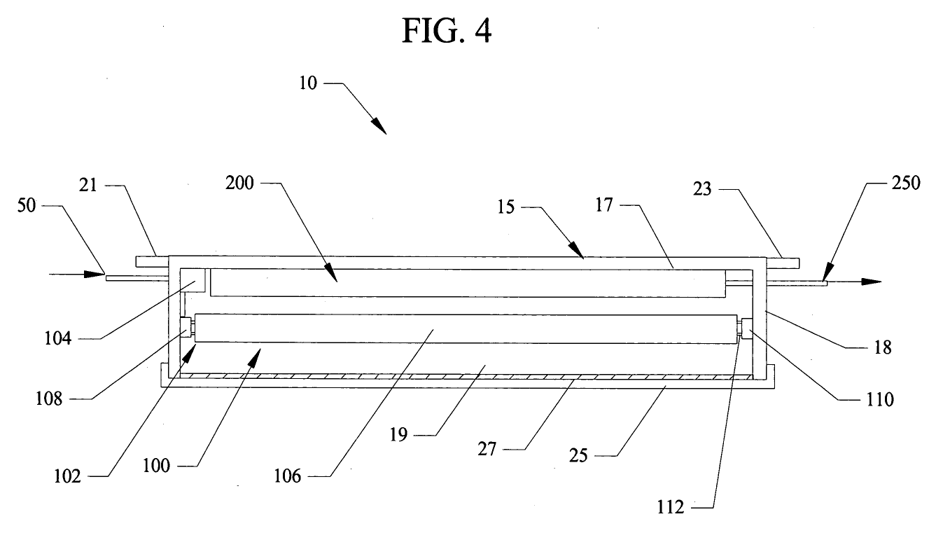

Referring now to FIG. 4, a preferred embodiment of the artificial light power generation system 10 is shown in which the system 10 takes the form of a ceiling mounted light fixture 12. In this embodiment, the light source 100 and photovoltaic panel 200 are disposed within a housing 15, which takes the form of a rectangular prism having a closed bottom 17 and sides 18 that define an open top 19. The housing 15 is dimensioned for mounting to a ceiling (riot shown). In the embodiment of FIG. 4, this is accomplished by a plurality of tabs 21, 23 that extend from the sides 18 proximate the closed bottom 17 and include screw holes (not shown) through which the housing 15 may be secured to a ceiling of the joists to which a ceiling is mounted. However, the manner in which the housing 15 is mounted to the ceiling will depend upon the style and configuration of the ceiling and the light fixture 12 and the tabs 21, 23 are intended to be merely illustrative of one way that this maybe accomplished.

In the embodiment of FIG. 4, the artificial light source 100 a fluorescent light fixture 102 made up of a ballast 104 connected to a source of power 50, a fluorescent bulb 106 and a pair of sockets 108, 110 that are dimensioned to accept the power pins 112 at each end of the bulb 106. The bulb 106 in FIG. 4 is preferably an T8 or T12 style ultraviolet fluorescent bulb of between 40 Watts and 80 Watts, which produces ultraviolet light that is readily absorbed by the photovoltaic panel 200 and converted into electrical energy. Because the ultraviolet radiation produced by ultraviolet fluorescent bulbs has been shown to increase the risk of certain types of skin cancers, it is preferred that embodiments that utilized UV bulbs will also utilize a light transmitting cover 25 that is attached to the housing 15 over the open top 19 and includes an ultraviolet filter 27 that is adapted to filter a substantial portion of ultraviolet rays passing therethrough.

In the embodiment of FIG. 4, light generated by the fluorescent bulb 106 shines downward through the cover 27 to illuminate the room below and simultaneously shines upward toward the photovoltaic panel 200, which absorbs light and converts this light into direct current electrical power which is fed through the direct current electrical output 250. As explained above, the direct current electrical output 250 may be connected directly to an inverter (hot shown) or may be connected in series to other light fixtures 12 prior to connecting to the inverter.

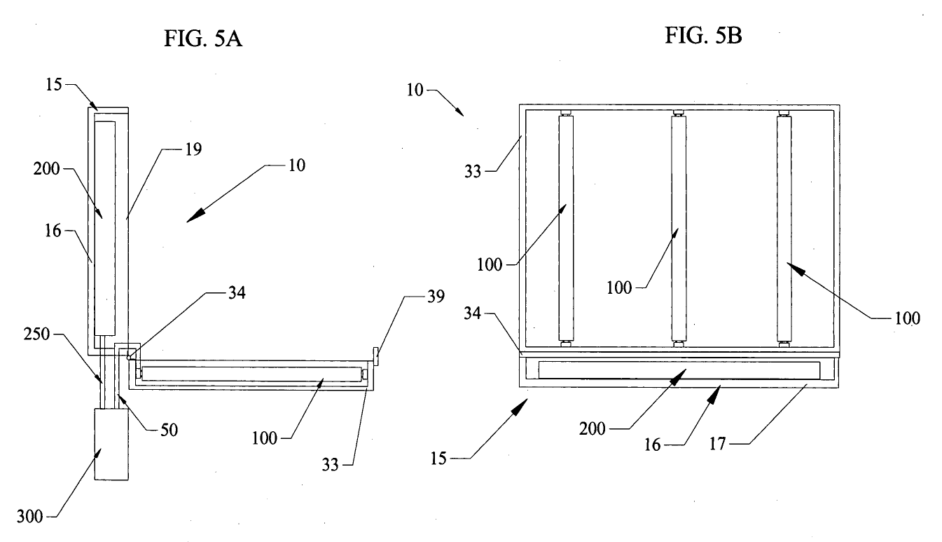

Referring now to FIGS. 5A and 5B, an embodiment of the system 10 in which light is used solely for power generation is shown. This embodiment of the invention, as well as those that follow, presume that the power required to generate light will continue to decrease and that the efficiency of photovoltaic cells and inverters will increase to the point where a photovoltaic cell may produce more power than the power required to generate the light absorbed by the photovoltaic cell.

The embodiment of FIGS. 5A and 5B includes a housing 15 having a base portion 16 and a front cover 33. The base portion 16 is shaped as a hollow rectangular prism having a closed bottom 17 and an open top 19. The front panel 33 is dimensioned to cover the open top 19 of the base portion 16 and is preferably rotatably attached to the base portion 16 via hinge 34. The photovoltaic panel 200 is preferably mounted to the closed bottom 17 of the base portion and a series of three light sources 100 are preferably attached to the front panel 33 such that the light sources 100 face the photovoltaic panel 200 when the front panel 33 is rotated and secured to the base portion by latch 39. The inverter 300 is preferably mounted below the housing 15 and is in communication with the photovoltaic panel 200 via the direct current output 250. In the embodiment of FIGS. 5A and 5B, the inverter 300 also provides the power input 50 to the light source. However, it is recognized that an additional power input 50, and/or a separate power input 50 may also be provided.

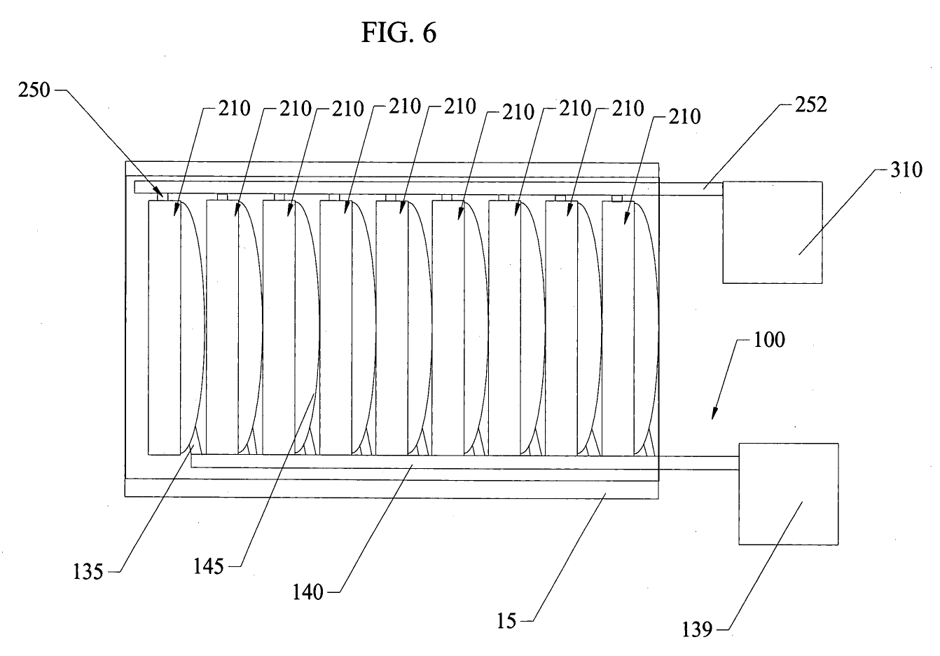

Referring now to FIG. 6, another alternative embodiment of the system 10 of the present invention for use in applications requiring mounting in small spaces, such as vehicles, is shown. In this embodiment, the housing 15 is a hollow cylinder in which a plurality of circular photovoltaic cells 210 is disposed. A domed reflective cover 145 is mounted to each photovoltaic cell 210 and the combined panels 200 and covers 145 are sandwiched together within the interior of the housing 15. In this embodiment, the light source 100 is a fiber optic source that includes a fiber optic generator 139 in communication with at least one fiber optic cable 140. The fiber optic cable include junction cables 135 that connect to each domed reflective cover 145, preferably via a rubber grommet (not shown) such that light enters the area between each cover 145 and each photovoltaic cell 210. The direct current output 250 of each photovoltaic cell 210 is connected in series to a common output cable 252, which provides direct current power out of the system to an inverter (not shown) and/or a direct current step-up transformer 310, which is used to provide power to the motor of the vehicle (not shown).

Although the present invention has been described in considerable detail with reference to certain preferred versions thereof, other versions would be readily apparent to those of ordinary skill in the art. Therefore, the spirit and scope of the appended claims should not be limited to the description of the preferred versions contained herein.

What is claimed is:

1. An artificial light power generation system comprising:
a housing;
at least one artificial light source disposed within said housing;
at least one photovoltaic panel disposed within said housing in light receiving relation to said at least one artificial light source, said at least one photovoltaic panel comprising at least one direct current electrical output though which direct current electrical power from said at least one photovoltaic panel flows; and
an inverter means for converting said direct current electrical power into alternating current electrical power, wherein said inverter means is in electrical communication with said at least one direct current electrical output of said at least one photovoltaic panel and comprises at least one alternating current electrical output though which alternating current electrical power from said inverter flows.

2. The artificial light power generation system as claimed in claim 1 further comprising a means for increasing a flow of current of said direct current electrical power, wherein said means for increasing a flow of current is disposed between, and in electrical communication with, said at least one photovoltaic panel and said inverter.

3. The artificial light power generation system as claimed in claim 2 wherein said means for increasing a flow of current of said direct current electrical power is an interface module.

4. The artificial light power generation system as claimed in claim 2 wherein said interface module is selected from a group consisting of a rheostat and a current transformer.

5. The artificial light power generation system as claimed in claim 2 wherein said means for increasing a flow of current of said direct current electrical power is a battery.

6. The artificial light power generation system as claimed in claim 2 wherein said at least one artificial light source comprise at least one fluorescent light fixture, wherein said housing is dimensioned for mounting to a ceiling and comprises a closed bottom and an open top, wherein said at least one photovoltaic panel is mounted proximate to said closed bottom of said housing and wherein said at least one fluorescent light fixture is mounted between said at least one photovoltaic panel and said open top of said housing such that light from said at least one fluorescent light fixture irradiates both said photovoltaic panel and an area below said housing.

7. The artificial light power generation system as claimed in claim 6 further comprising a light transmitting cover attached to said housing, wherein said cover is dimensioned to enclosed at least a portion of said open top of said housing.

8. The artificial light power generation system as claimed in claim 7 wherein at least one of said at least one fluorescent light fixture is an ultraviolet fluorescent light fixture and wherein said light transmitting cover comprises an ultraviolet filter for filtering a substantial portion of ultraviolet rays passing therethrough.

9. The artificial light power generation system as claimed in claim 2 wherein said housing comprises a base portion shaped as a hollow rectangular prism having an open top and a front panel dimensioned to cover said open top of and prevent a substantially amount of light from escaping from said housing.

10. The artificial light power generation system as claimed in claim 9 wherein said front panel of said housing is rotatably attached to said base portion of said housing.

11. The artificial light power generation system as claimed in claim 10 wherein at least one artificial light source is attached to said front panel of said housing.

12. The artificial light power generation system as claimed in claim 2 further comprising a power controller in electrical communication with said inverter, an electrical supply panel, and a power grid, wherein said power controller controls a flow of power to said electrical supply panel from said inverter and said power grid.

13. The artificial light power generation system as claimed in claim 12 wherein said inverter is a grid-tie inverter and wherein said power controller controls a flow of power to said electrical supply panel from said inverter and said power grid and a flow of power to said power grid from said inverter.

14. The artificial light power generation system as claimed in claim 12 wherein said means for increasing a flow of current of said direct current electrical power is a battery, wherein said system further comprises a communication link between said battery and said power controller, and wherein said power controller controls a flow of power from said battery to said inverter and controls a flow of power to said electrical supply panel from said inverter and said power grid.

15. The artificial light power generation system as claimed in claim 2 wherein said at least one light source comprises at least one fiber optic light source.

16. An artificial light power generation system comprising:
a housing;
at least fiber optic light source disposed within said housing;
at least one photovoltaic cell disposed within said housing in light receiving relation to said at least one fiber optic light source, said at least one photovoltaic cell comprising at least one direct current electrical output though which direct current electrical power from said at least one photovoltaic cell flows; and
a means for increasing a flow of current of said direct current electrical power, wherein said means for increasing a flow of current is disposed between, and in electrical communication with, said at least one photovoltaic panel.

17. The artificial light power generation system as claimed in claim 16 wherein said means for increasing a flow of current comprises a direct current step-up transformer.

18. The artificial light power generation system as claimed in claim 17 wherein said at least one photovoltaic cell comprises a plurality of photovoltaic cells and wherein each of said plurality of photovoltaic panels is in light receiving communication with at least one of said at least one fiber optic light source.

19. The artificial light power generation system as claimed in claim 18 further comprising a plurality of reflective covers, wherein each of said plurality of reflective covers is disposed in light reflecting relation to one of said plurality of photovoltaic cells.

20. The artificial light power generation system as claimed in claim 19 wherein said housing comprises a hollow cylindrical prism having an interior surface of substantially circular cross section, wherein each of said plurality of photovoltaic cells is substantially circular, wherein each of said plurality of reflective covers is dome shaped, wherein said photovoltaic cells and said domed shaped reflective covers are stacked within said interior surface of said housing, and wherein said at least one fiber optic light source comprises a single fiber optic light source in communication with each of said plurality of photovoltaic cells.
